(19) United States
(12) Patent Application Publication
(10) Pub. No.: US 2024/0249965 A1
(43) Pub. Date: Jul. 25, 2024

(54) SUBSTRATE SUPPORT CARRIER HAVING MULTIPLE CERAMIC DISCS

(71) Applicant: Applied Materials, Inc., Santa Clara, CA (US)

(72) Inventors: Arvinder Manmohan Singh CHADHA, San Jose, CA (US); Jonathan SIMMONS, San Jose, CA (US); Stephen Donald PROUTY, San Jose, CA (US); Christopher BEAUDRY, Santa Clara, CA (US); Glen T. MORI, Gilroy, CA (US); Anand DURAIRAJAN, San Jacinto, CA (US)

(21) Appl. No.: 18/099,210

(22) Filed: Jan. 19, 2023

(51) Int. Cl. H01L 21/683; H01L 21/687

(52) U.S. Cl. CPC H01L 21/6833; H01L 21/68735; H01L 21/68757

(57) ABSTRACT

A substrate support carrier includes an electrostatic chuck (ESC) assembly includes a top ceramic disc having a recess formed from a lower surface of the top ceramic disc, a bottom ceramic disc having a hole through the bottom ceramic disc, an upper bonding layer interposed between the lower surface of the top ceramic disc and an upper surface of the bottom ceramic disc, and a porous plug within at least one of the recess of the top ceramic disc and the hole of the bottom ceramic disc, a temperature control base, and a lower bonding layer interposed between a lower surface of the bottom ceramic disc and an upper surface of the temperature control base.

### BACKGROUND

### Field

Embodiments of the present disclosure generally relate to a substrate support carrier having porous features embedded therein for use in a substrate processing chamber, and more particularly, to a substrate support carrier having multiple ceramic discs.

### Description of the Related Art

Electrostatic chucks are utilized in a variety of manufacturing and processing operations. In semiconductor manufacturing, electrostatic chucks are used to support a substrate in a processing chamber. Currently, electrostatic chucks use a single ceramic disc in which clamp electrodes and resistive heaters are embedded. Some electrostatic chucks further incorporate one press-fitted or glued porous plug within the ceramic disc. This design utilizes mechanical means of securing the porous plug within the single ceramic disc, for example, holding the porous plug in a dielectric sleeve by a press or interference fit. Careful machining is required to provide this fit. Additional complications are associated with preventing undesirable cracking of the ceramic disc during the manufacture or operation of the electrostatic chuck.

Therefore, there is a need for an electrostatic chuck that can be manufactured and operated with reduced complications.

### SUMMARY OF THE DISCLOSURE

Embodiments of the present disclosure provide a substrate support carrier for use in a processing chamber. The substrate support carrier includes an electrostatic chuck (ESC) assembly includes a top ceramic disc having a recess formed from a lower surface of the top ceramic disc, a bottom ceramic disc having a hole through the bottom ceramic disc, an upper bonding layer interposed between the lower surface of the top ceramic disc and an upper surface of the bottom ceramic disc, and a porous plug within at least one of the recess of the top ceramic disc and the hole of the bottom ceramic disc, a temperature control base, and a lower bonding layer interposed between a lower surface of the bottom ceramic disc and an upper surface of the temperature control base.

Embodiments of the present disclosure also provide a substrate support carrier for use in a processing chamber. The substrate support carrier includes an electrostatic chuck (ESC) assembly includes a top ceramic disc, and a bottom ceramic disc, an upper bonding layer interposed between a lower surface of the top ceramic disc and an upper surface of the bottom ceramic disc, a temperature control base, a lower bonding layer interposed between a lower surface of the bottom ceramic disc and an upper surface of the temperature control base, and a bond edge protection feature disposed at edges of at least one of the upper bonding layer and the lower bonding layer.

Embodiments of the present disclosure further provide an electrostatic chuck (ESC) assembly. The ESC assembly includes a top ceramic disc having a clamp electrode embedded therein, a bottom ceramic disc having a plurality of resistive heaters embedded therein, a bonding layer interposed between a lower surface of the top ceramic disc and an upper surface of the bottom ceramic disc, a first electrical feedthrough connected to the clamp electrode, a plurality of second electrical feedthroughs each connected to one of the plurality of resistive heaters and routed within the bottom ceramic disc to the lower surface of the bottom ceramic disc, and a plurality of electrical terminals brazed at the lower surface of the lower surface of the bottom ceramic disc.

### BRIEF DESCRIPTION OF DRAWINGS

So that the manner in which the above recited features of the present disclosure are attained and can be understood in detail, a more particular description of the disclosure, briefly summarized above, may be had by reference to the embodiments thereof which are illustrated in the appended drawings. It is to be noted, however, that the appended drawings illustrate only embodiments of this disclosure and are therefore not to be considered limiting of its scope, for the disclosure may admit to other equally effective embodiments.

FIG. 1 is a schematic cross-sectional view of an exemplary substrate support carrier for use in a processing chamber.

FIGS. 2A, 2B, and 2C depict cross-sectional views of porous plugs having in-situ sleeves, according to one or more embodiments.

FIGS. 3A, 3B, 3C, 3D, 3E, 3F, 3G, 3H, 3I, 3J, 3K, 3L, 3M, 3N, 3O, 3P, 3Q, 3R, 3S, 3T, 3U, 3V, 3W, 3X, and 3Y are cross-sectional views of a portion of an electrostatic chuck (ESC) assembly, according to one or more embodiments.

FIGS. 4A, 4B, 4C, 4D, 4E, 4F, 4G, 4H, 4I, 4J, 4K, 4L, 4M, 4N, 4O, 4P, 4Q, 4R, 4S, 4T, and 4U are cross-sectional views of a portion of a substrate support carrier, according to one or more embodiments.

FIGS. 5A, 5B, 5C, 5D, and 5E are cross-sectional views of a portion of a substrate support carrier, according to one or more embodiments.

To facilitate understanding, identical reference numerals have been used, wherever possible, to designate identical elements that are common to the figures.

### DETAILED DESCRIPTION

Embodiments described herein provide a substrate support carrier having multiple ceramic discs with a bonding layer interposed between the ceramic discs. In one ceramic disc, clamp electrodes are embedded. In the other ceramic disc, resistive heaters are embedded. The embodiments described herein provide assemblies of a porous plug that extends through the multiple ceramic discs and the boding layer, configurations of protecting the bonding layer from erosion, and electrical routing that connects the clamp electrodes and the resistive heaters to power sources.

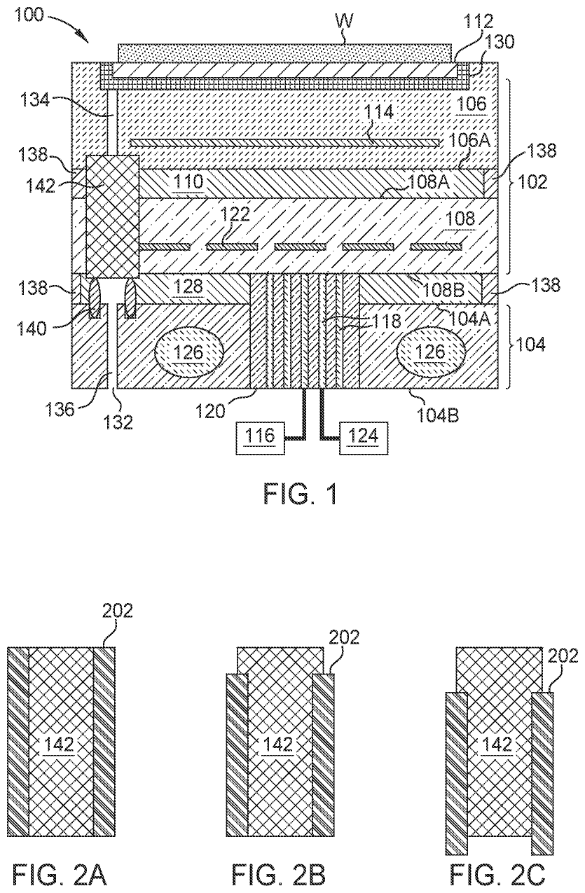

FIG. 1 is a schematic cross-sectional view of an exemplary substrate support carrier 100 for use in a processing chamber. The substrate support carrier 100 includes an electrostatic chuck (ESC) assembly 102 and a temperature control base 104. The ESC assembly 102 includes a top ceramic disc 106 and a bottom ceramic disc 108. The top ceramic disc 106 and the bottom ceramic disc 108 are each formed of ceramic material, such as alumina, aluminum nitride, sapphire, or zirconia. The top ceramic disc 106 and the bottom ceramic disc 108 may have different functionalities (e.g., the top ceramic disc 106 includes clamping electrodes embedded therein, and the bottom ceramic disc 108 includes resistive heaters embedded therein, as described below), and may be formed of different ceramic materials suitable for their functionalities. A bonding layer (referred to as an “upper bonding layer” hereinafter) 110 is interposed between a lower surface 106A of the top ceramic disc 106 and an upper surface 108A of the bottom ceramic disc 108 that faces the top ceramic disc 106. The upper bonding layer 110 secures, and thermally couples the top ceramic disc 106 to the bottom ceramic disc 108. The temperature control base 104 is formed of a metal such as aluminum. The temperature control base 104 is fixed to a cylindrical support post (not shown) which extends through a wall of a processing chamber to support the substrate support carrier 100 thereon. The substrate support carrier 100 may generally have a circular shape but other shapes, such as rectangular or ovoid, capable of supporting a substrate W may be utilized.

The top ceramic disc 106 includes an upper surface 112 for supporting a substrate W thereon. Clamp electrodes 114 (one shown in FIG. 1) are embedded within the top ceramic disc 106. The clamp electrodes 114 are each connected to a power source 116 thorough an electrical feedthrough (not shown in FIG. 1) that is routed through the ESC assembly 102 and connected to electrical terminals (e.g., Kovar pins, Pogo pins) 118 within an insulating interface 120 at a lower surface 108B of the bottom ceramic disc 108. The insulating interface 120 may be disposed within the temperature control base 104. The power source 116 imposes a voltage on the clamp electrode 114 to form an electromagnetic field at an interface of the upper surface 112 of the top ceramic disc 106 and the substrate W. The electromagnetic field interacts with the substrate W to chuck the substrate W to the upper surface 112 of the top ceramic disc 106. The clamp electrode 114 may be biased to provide either a monopolar or a bipolar chuck.

Resistive heaters 122 are embedded within the bottom ceramic disc 108. The resistive heaters 122 are connected to a power source 124 through electrical feedthroughs (not shown in FIG. 1) that are routed within the bottom ceramic disc 108 and connected to electrical terminals (e.g., Kovar pins) 118 within the insulating interface 120 at the lower surface 108B of the bottom ceramic disc 108.

It should be noted that the particular example embodiments described herein are just some possible examples of an ESC assembly having multiple ceramic discs according to the present disclosure and do not limit the possible configurations, specifications, or the like of an ESC assembly according to the present disclosure. For example, an ESC assembly may include three ceramic discs, in which an additional ceramic disc having resistive heaters and radio frequency (RF) electrodes embedded therein, RF electrodes embedded therein, gas distribution channels embedded therein. The additional ceramic disc may be placed between the bottom ceramic disc 108 and the temperature control base 104, or between the top ceramic disc 106 and the bottom ceramic disc 108. In another example, resistive heaters and/or RF electrodes may be embedded in the top ceramic disc 106 or in the bottom ceramic disc 108.

The temperature control base 104 includes channels 126 disposed therein to circulate a fluid through the temperature control base 104. The fluid, typically a liquid such as GALDEN®, flows from a temperature control unit (not shown) through the channels 126 and back to the temperature control unit. In certain processes, the fluid is used to cool the temperature control base 104 in order to lower the temperature of the ESC assembly 102 and the substrate W disposed thereon. Conversely, the fluid may be used to elevate temperature of the temperature control base 104 to heat the ESC assembly 102 and the substrate W thereon. In some cases, heat from the resistive heaters 122, in combination with heat transfer from the temperature control base 104 into the fluid, is used to maintain the ESC assembly 102 or the substrate W at a setpoint temperature.

A bonding layer (referred to as a “lower bonding layer” hereinafter) 128 is interposed between the lower surface 108B of the bottom ceramic disc 108 and an upper surface 104A of the temperature control base 104 which faces the bottom ceramic disc 108. The upper surface 104A of the temperature control base 104 is opposite a lower surface 104B of the temperature control base 104 which is coupled to the cylindrical support post. The lower bonding layer 128 secures, and thermally couples the bottom ceramic disc 108 to the temperature control base 104.

The upper bonding layer 110 and the lower bonding layer 128 may be formed of metal bond material such as aluminum, manganese molybdenum, platinum, nickel, platinum nickel composite or a combination of thereof, aluminum silicon carbide (AlSiC), molybdenum (Mo), or aluminum oxide (alumina, Al₂O₃), or organic bond material such as silicone resin, or acrylic resin.

The ESC assembly 102 may further include a gas channel 130 embedded in the top ceramic disc 106. In some embodiments, gas channels (not shown) are embedded in the temperature control base 104. A backside gas (e.g., helium, nitrogen, or argon) is supplied by a gas source (not shown) through a flow aperture 132 and the gas channel 130 to aid in the control the temperature across the substrate W when it is retained by the ESC assembly 102. The gas channel 130 may have a diameter of between about 1 μm and about 5 mm.

The flow aperture 132 is disposed within the substrate support carrier 100. As shown in FIG. 1, the flow aperture 132 extends from the lower surface 104B of the temperature control base 104 to the gas channel 130. The flow aperture 132 includes a first opening 134 formed through the ESC assembly 102 and the lower bonding layer 128, and a second opening 136 is formed through the temperature control base 104. The second opening 136 is aligned with the first opening 134 such that the second opening 136 and the first opening 134 have at least 10% overlap. The gas is maintained at a pressure sufficient to cause the gas to function as a heat conduction path between the substrate W and the ESC assembly 102. The first opening 134 and the second opening 136 of the flow aperture 132 may have a height of between about 1 μm and about 20 mm and a width of between about 10 μm and about 10 mm.

During processing, some gases are known to degrade the upper bonding layer 110 and the lower bonding layer 128 that are exposed to the gas at the flow apertures 132 and/or exposed portions at the periphery of the substrate support carrier 100. In order to isolate the upper bonding layer 110 and the lower bonding layer 128 from the process gases, seals 138 are disposed around the periphery of the upper bonding layer 110 and the periphery of the lower bonding layer 128, and an O-ring 140 is disposed in the first opening 134 of the flow aperture 132 formed within the lower bonding layer 128. In some embodiments, seals 138 are disposed around the periphery of the upper bonding layer 110 or the periphery of the lower bonding layer 128. The seal 138 and the O-ring 140 are formed of material resistant to degradation from exposure to the process gases. In this example, the seal 138 and the O-ring 140 each contact, and are compressed between, the temperature control base 104 and the bottom ceramic disc 108 which prevents flow of a process gas thereby isolating the lower bonding layer 128.

A porous plug 142 is optionally disposed within the ESC assembly 102 in the first opening 134 of the flow aperture 132. The porous plug 142 is formed of porous metal material such as metal nitrides (e.g., aluminum nitride (AlN)), metal carbides, metal silicides, metal oxides (e.g., aluminum oxide (Al₂O₃)), or combination thereof, or a porous semiconductor material which may be nitrides, carbides, silicides, oxides, or combination thereof. The porous plug 142 has pores having a size of between about 10 nm and about 100 μm and a porosity, such as a range of porosity between about 5% and about 95%. The porosity may be in a form of features, such as holes or channels, disposed in a periodic or an aperiodic manner within the porous plug 142, which allows the passage of the gas from an area of the first opening 134 proximate to the second opening 136, through the porous plug 142, and in fluid communication with the gas channel 130. The porous plug 142 further prevents ionized particles or ionized gas from passing from a processing area in the processing chamber, and into the isolated portion of the volume defined by openings 134, 136 when the substrate W is not disposed on the top ceramic disc 106. The porous plug 142 may have a diameter of between about 0.5 μm and about 5 mm, for example, about 1 mm. The porous plug 142 may be cylinder shaped or mushroom shaped having a wider portion at an end of the porous plug 142.

In some embodiments, the porous plug 142 has an in-situ sleeve 202 at least partially encapsulating the porous plug 142, as shown in FIGS. 2A, 2B, and 2C. The in-situ sleeve 202 may be formed during fabrication of the porous plug 142. The in-situ sleeve 202 may have a thickness of between about 0.1 μm and about 3 mm. The in-situ porous plug can be manufactured from metal oxide or metal nitride ceramic material, for example, aluminum oxide (Al₂O₃), aluminum nitride (AlN), titanium oxide (TiO), titanium nitride (TiN), yttrium oxide (Y₂O₃), mixtures thereof, and combinations thereof. The in-situ sleeve 202 may have the same lengths as the porous plug 142, entirely encapsulating the porous plug 142 in FIG. 2A. The in-situ sleeve 202 may have a shorter length than the porous plug 142, partially encapsulating the porous plug 142 in FIG. 2B. The in-situ sleeve 202 may partially encapsulate the porous plug 142 and extend beyond the porous plug 142 in FIG. 2C.

### Porous Plug Assembly in ESC Assembly

As shown in FIG. 1, the porous plug 142 extends through the ESC assembly 102, including the top ceramic disc 106, the bottom ceramic disc 108, and the upper bonding layer 110 interposed between the top ceramic disc 106 and the bottom ceramic disc 108. The porous plug 142 may extend within the top ceramic disc 106, the bottom ceramic disc 108, or both of the top ceramic disc 106 and the bottom ceramic disc 108. Methods of forming a porous plug 142 that extends through the ESC assembly 102, as shown in FIG. 1, are described herein.

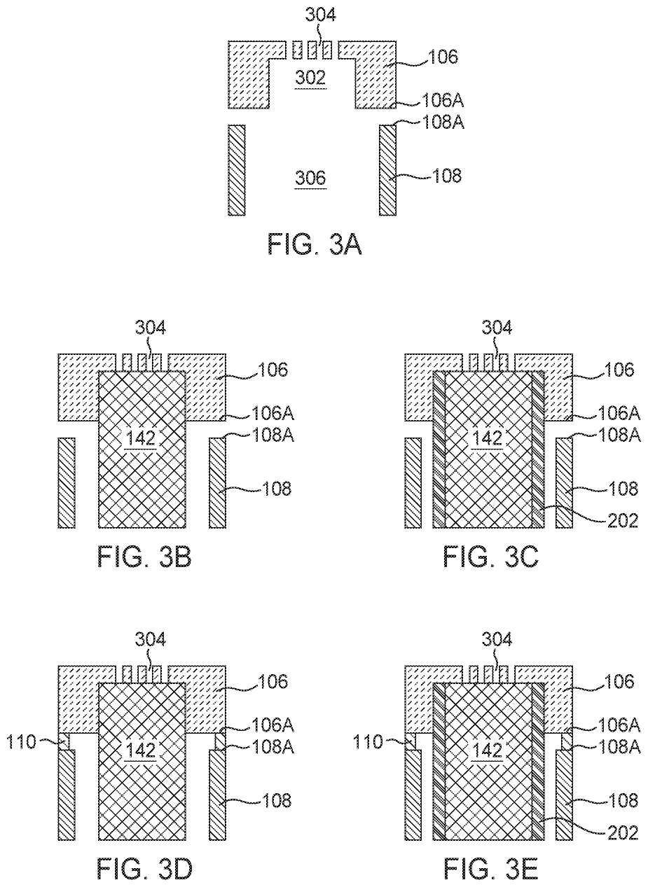

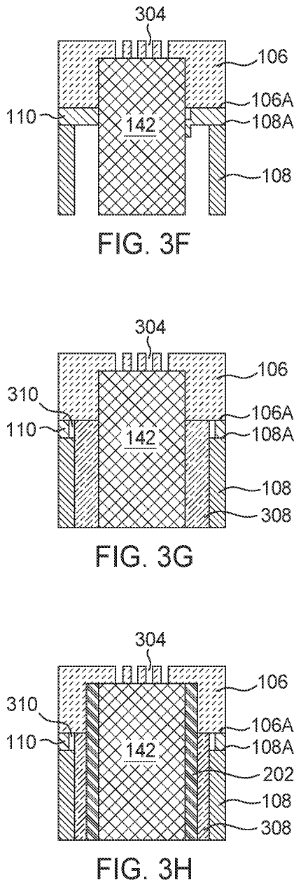

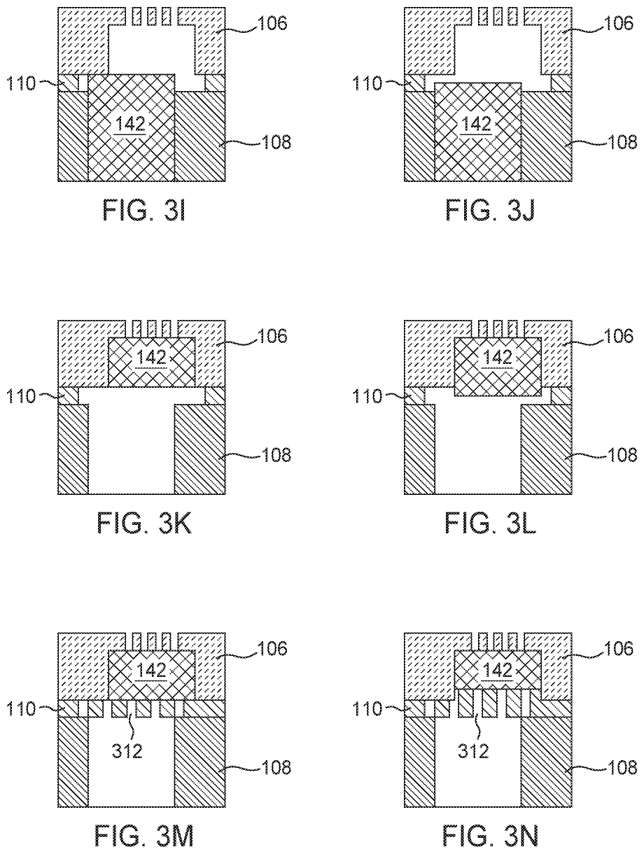

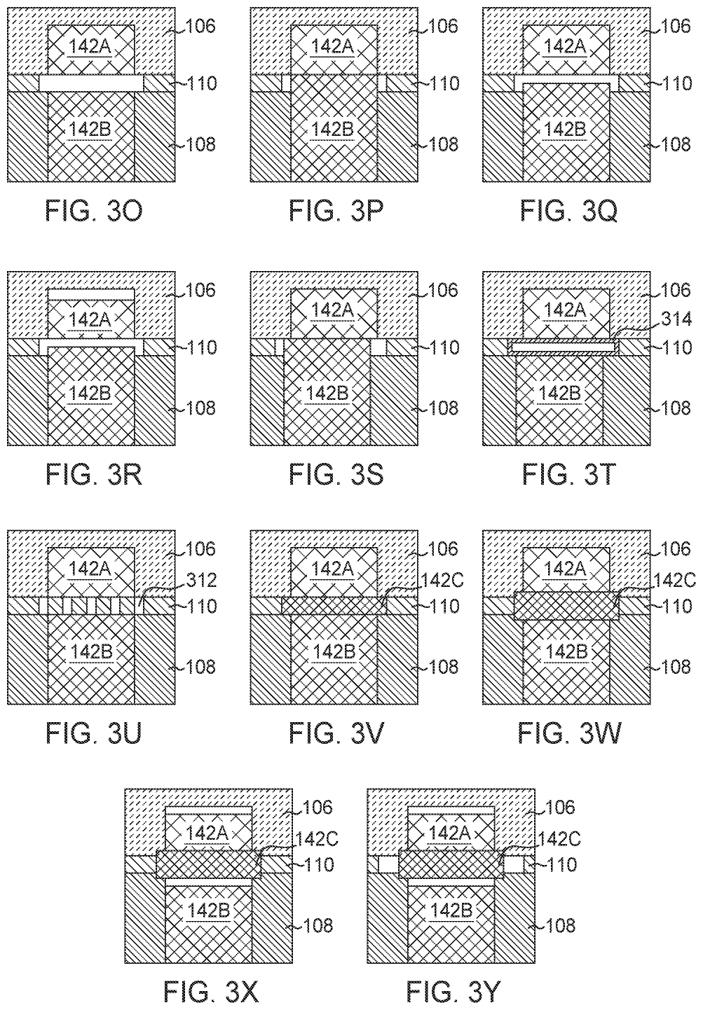

First, a top ceramic disc 106 and a bottom ceramic disc 108 are patterned, as shown in FIG. 3A. In some embodiments, the top ceramic disc 106 and the bottom ceramic disc 108 are sintered ceramic bodies formed of ceramic material, such as alumina, aluminum nitride, sapphire, or zirconia, by any appropriate ceramic forming methods, such as hot isostatic pressing (HIP), tape casting. In the patterning, a recess 302 from a lower surface 106A of the top ceramic disc 106, vanes 304 from the recesses 302 within the top ceramic disc 106, and a hole 306 through the bottom ceramic disc 108, may be formed by micro-machining, such as drilling or laser ablation. The recess 302 and the hole 306 may have different sizes or the same size. The recess 302 and the hole 306 are aligned such that the recess 302 and the hole 306 have at least 10% overlap at the lower surface 106A of the top ceramic disc 106 and the upper surface 108A of the bottom ceramic disc 108.

### 1. Single Porous Plug Design

In some embodiments, the porous plug 142 is formed of a single porous plug covering a majority of both of the top ceramic disc 106 and the bottom ceramic disc 108. As shown in FIGS. 3B and 3C, a single porous plug 142 is disposed in the recess 302 of the top ceramic disc 106. The porous plug 142 may include the in-situ sleeve 202 encapsulating the porous plug 142, as shown in FIG. 3C. The porous plug 142 may have a length that is longer than the depth of the recess 302 and thus extend into the hole 306 of the bottom ceramic disc 108. The porous plug 142 (and the in-situ sleeve 202 if included) may be press-fitted into the recess 302 of the top ceramic disc 106. The porous plug 142 (and the in-situ sleeve 202 if included) may be bonded to inner surfaces of the recess 302 of the top ceramic disc 106 using an adhesive.

Subsequent to or prior to the deposition of the single porous plug 142, the top ceramic disc 106 and the bottom ceramic disc 108 are bonded with the upper bonding layer 110 interposed between the lower surface 106A of the top ceramic disc 106 and the upper surface 108A of the bottom ceramic disc 108, as shown in FIGS. 3D, 3E, and 3F. In some embodiments, the top ceramic disc 106 and the bottom ceramic disc 108 are bonded simultaneously with bonding of the bottom ceramic disc 108 to the temperature control base 104. The upper bonding layer 110 may terminate without contacting the porous plug 142 (and the in-situ sleeve 202 if included), as shown in FIGS. 3C and 3D. The upper bonding layer 110 may at least partially contact the porous plug 142, as shown in FIG. 3F. In some embodiments, the upper bonding layer 110 is a metal bonding layer formed of aluminum, manganese molybdenum, platinum, nickel, platinum nickel composite or a combination of thereof, aluminum silicon carbide (AlSiC), molybdenum (Mo), aluminum oxide (alumina, Al₂O₃), or other suitable metal bond material, and the bonding process is performed at a temperature of between about 300° C. and about 1,500° C. In some embodiments, the upper bonding layer 110 is an organic bonding layer formed of silicone resin, acrylic resin, or other suitable organic bond material, and the bonding process is performed at a temperature of between about 20° C. and about 300° C. The temperature ranges of the bonding process are selected such that an adhesive agent in the bond material does not burn at a high temperature, and does not remain at a low temperature.

An external sleeve 308 may be further disposed around the porous plug 142 (and the in-situ sleeve 202 if included), as shown in FIGS. 3G and 3H. In the examples shown in FIGS. 3G and 3H, the external sleeve 308 does not extend into the top ceramic disc 106. However, in some other embodiments, the recess 302 (shown in FIG. 3A) of the top ceramic disc 106 may be wider than the hole 306 (shown in FIG. 3A) of the bottom ceramic disc 108 to allow the external sleeve 308 to extend into the recess 302 of the top ceramic disc 106, leaving a small gap (e.g., 10 μm-1 mm) between the external sleeve 308 and the inner surfaces of the recess 302 of the top ceramic disc 106. The external sleeve 308 may be formed of insulating plastics such as polyetheretherketone (PEEK), Ultem® (polyetherimide), or dielectrics such as alumina or alumina nitride-. The external sleeve 308 may further assist in preventing particle generation from plasma-bond material interaction. The external sleeve 308 may further prevent wafer to bond arcing if the metal bond material is incorporated. A gap 310 between the upper bonding layer 110 and the external sleeve 308 is filled with dielectric material (e.g., air or polymer) to suppress particle generation and prevent wafer to bond arcing.

In some embodiments, the porous plug 142 is formed of a single porous plug covering a majority of either of the top ceramic disc 106 or the bottom ceramic disc 108. As shown in FIGS. 31 and 3J, the porous plug 142 covers a majority of the hole 306 (shown in FIG. 3A) of the bottom ceramic disc 108 and does not extend into the recess 302 (shown in FIG. 3A) of the top ceramic disc 106. The porous plug 142 may extend beyond the hole 306 of the bottom ceramic disc 108 to the lower surface 106A (shown in FIG. 3A) of the top ceramic disc 106, as shown in FIG. 3I, or partially to the lower surface 106A of the top ceramic disc 106, as shown in FIG. 3J. As shown in FIGS. 3K, 3L, 3M, and 3N, the porous plug 142 covers a majority of the recess 302 of the top ceramic disc 106 and does not extend into the hole 306 of the bottom ceramic disc 108. As shown in FIG. 3L, the porous plug 142 may extend partially to the upper surface 108A (shown in FIG. 3A) of the bottom ceramic disc 108. The upper bonding layer 110 may terminate without contacting the porous plug 142, as shown in FIGS. 3I, 3J, 3K, and 3L. The upper bonding layer 110 may contact the porous plug 142, as shown in FIGS. 3M and 3N, in which the upper bonding layer 110 includes through holes 312 that at least partially overlap with porous features in the porous plug 142. The porous plug 142 in the recess 302 (shown in FIG. 3A) of the top ceramic disc 106 may have a length shorter than the depth of the top ceramic disc 106, and the upper bonding layer 110 protrudes into the remaining of the recess 302 of the top ceramic disc 106, as shown in FIG. 3N.

### 2. Multi Porous Plug Design

In some embodiments, the porous plug 142 is formed of a top porous plug 142A covering a majority of the top ceramic disc 106 and a bottom porous plug 142B covering a majority of the bottom ceramic disc 108, as shown in FIGS. 3O, 3P, 3Q, 3R, 3S, 3T, 3U, 3V, 3W, 3X, and 3Y. The top porous plug 142A may be press-fitted into the recess 302 (shown in FIG. 3A) of the top ceramic disc 106, or bonded to inner surfaces of the recess 302 of the top ceramic disc 106 using an adhesive. The bottom porous plug 142B may be press-fitted into the hole 306 (shown in FIG. 3A) of the bottom ceramic disc 108, or bonded to inner surfaces of the hole 306 (shown in FIG. 3A) of the bottom ceramic disc 108. In some embodiments, the top porous plug 142A is manufactured monolithically as a part of the top ceramic disc 106, and the bottom porous plug 142B is manufactured monolithically as a part of the bottom ceramic disc 108.

The upper bonding layer 110 may terminate without contacting the top porous plug 142A or the bottom porous plug 142B, as shown in FIGS. 3O, 3P, 3Q, 3R, and 3S. The upper bonding layer 110 may contact the top porous plug 142A and/or the bottom porous plug 142B, as shown in FIG. 3U, in which the upper bonding layer 110 includes through holes 312 that at least partially overlap with porous features in the top porous plug 142A and in the bottom porous plug 142B.

The top porous plug 142A and the bottom porous plug 142B may at least partially contact each other, as shown in FIGS. 3P and 3S. The top porous plug 142A and the bottom porous plug 142B may not contact each other having a gap therebetween, as shown in FIGS. 3O, 3Q, and 3R. The top porous plug 142A has the same length as the depth of the recess 302 (shown in FIG. 3A) of the top ceramic disc 106, covering the entire recess 302, as shown in 3O, 3P, 3Q, 3S, 3T, 3U, 3V, and 3W. The top porous plug 142A may have a length that is shorter than the depth of the recess 302 (shown in FIG. 3A) of the top ceramic disc 106, leaving a gap between the top ceramic disc 106 and the top porous plug 142A, as shown in FIGS. 3R, 3X, and 3Y. The top porous plug 142A and the bottom porous plug 142B may not be aligned with each other, but have an overlap, as shown in FIGS. 3S and 3T. As shown in in FIG. 3T, a dielectric sleeve 314 formed of metal oxide or metal nitride ceramic material, for example, aluminum oxide (Al₂O₃), aluminum nitride (AlN), titanium oxide (TiO), titanium nitride (TiN), yttrium oxide (Y₂O₃), mixtures thereof, and combinations thereof. Dielectric sleeve may comprise of plastics, such as polyetheretherketone (PEEK), or Ultem® (polyetherimide), may be disposed between the top porous plug 142A and the bottom porous plug 142B. The dielectric sleeve 314 may serve as an insulation to prevent particulate formation upon plasma-bond material interaction. In cases where the bond material is substantially conductive, the dielectric sleeve 314 may assist in suppressing the light up in the gas hole and arcing of the wafer to the cooling plate

As shown in FIGS. 3V, 3W, 3X, and 3Y, the porous plug 142 may include a center porous plug 142C between the top porous plug 142A and the bottom porous plug 142B. The center porous plug 142C may be disposed within an opening in the upper bonding layer 110, as shown in FIG. 3V. The center porous plug 142C may protrude into the top ceramic disc 106 and the bottom ceramic disc 108, as shown in FIGS. 3W, 3X, and 3Y. The upper bonding layer 110 may contact the center porous plug 142C, as shown in FIGS. 3V, 3W, and 3X. The upper bonding layer 110 may terminate without contacting the center porous plug 142C, as shown in FIG. 3Y. The center porous plug 142C may contact the bottom porous plug 142B, as shown in FIGS. 3V, 3W, 3X, and 3Y. The center porous plug 142C and the bottom porous plug 142B may not contact each other having a gap therebetween, as shown in FIG. 3Y.

### Bond Edge Protection in ESC Assembly

The substrate support carrier 100, including the ESC assembly 102, is exposed to process gases and process reaction byproducts of a substrate processing performed within a processing chamber. Some of these gases and byproducts, when coming into the upper bonding layer 110 interposed between the top ceramic disc 106 and the bottom ceramic disc 108 in the ESC assembly 102, can deteriorate and erode the upper bonding layer 110. Embodiments of the ESC assembly 102, in which bond edge protection features are disposed at the periphery of the upper bonding layer 110 and/or in the first opening 134 (shown in FIG. 1) in the upper bonding layer 110, are described herein.

1. Bond Edge Protection with Interleaving Features at Peripheral Edge

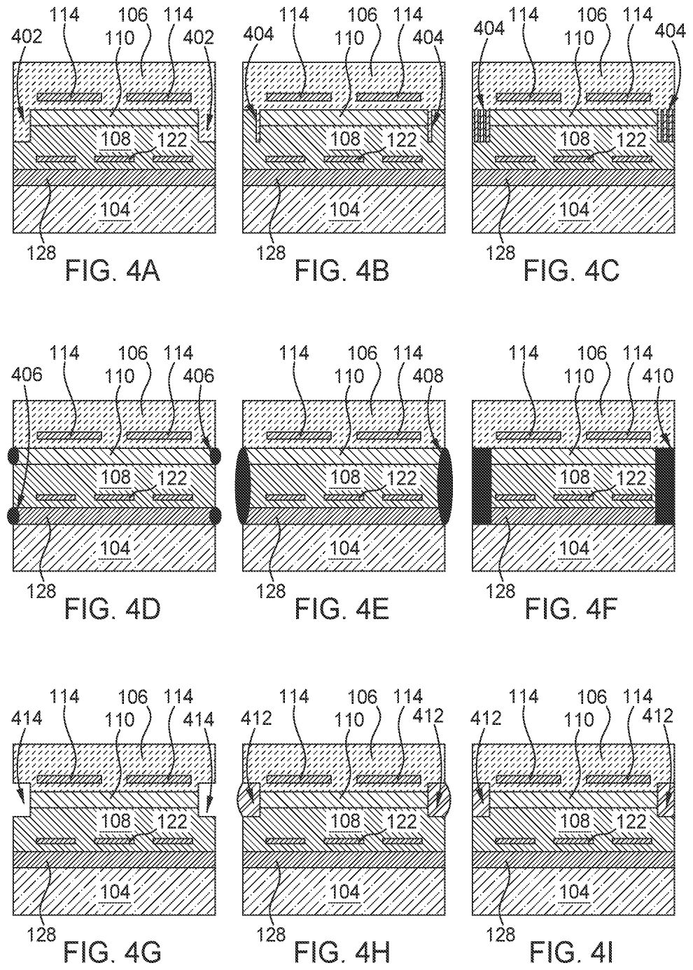

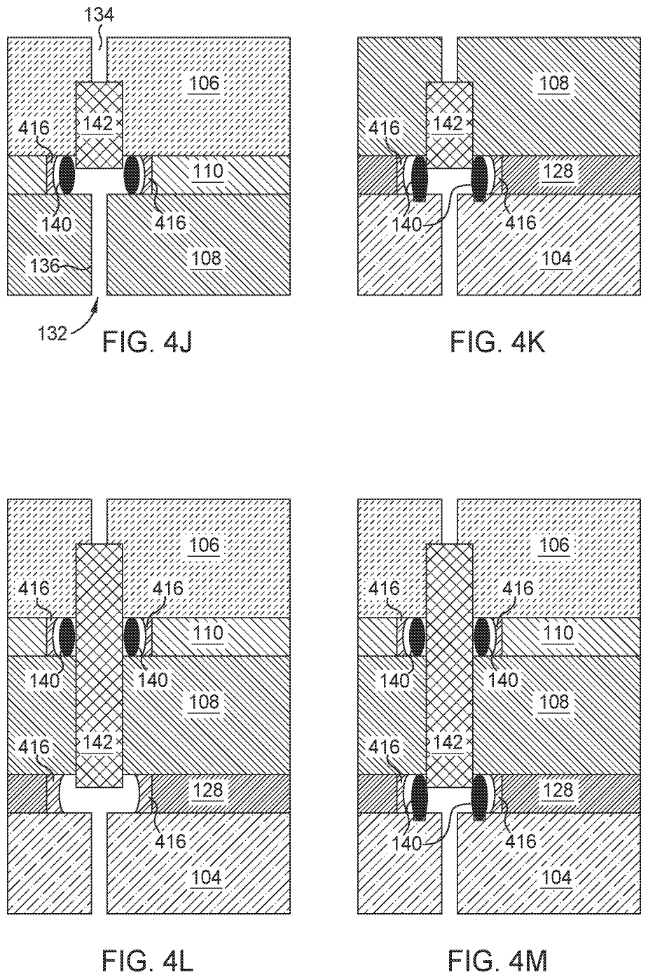

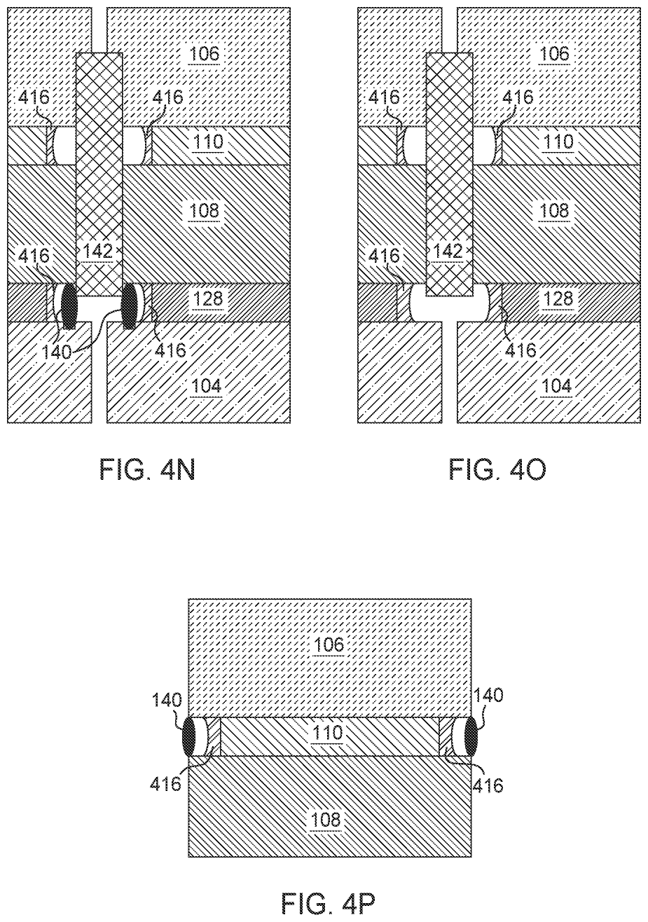

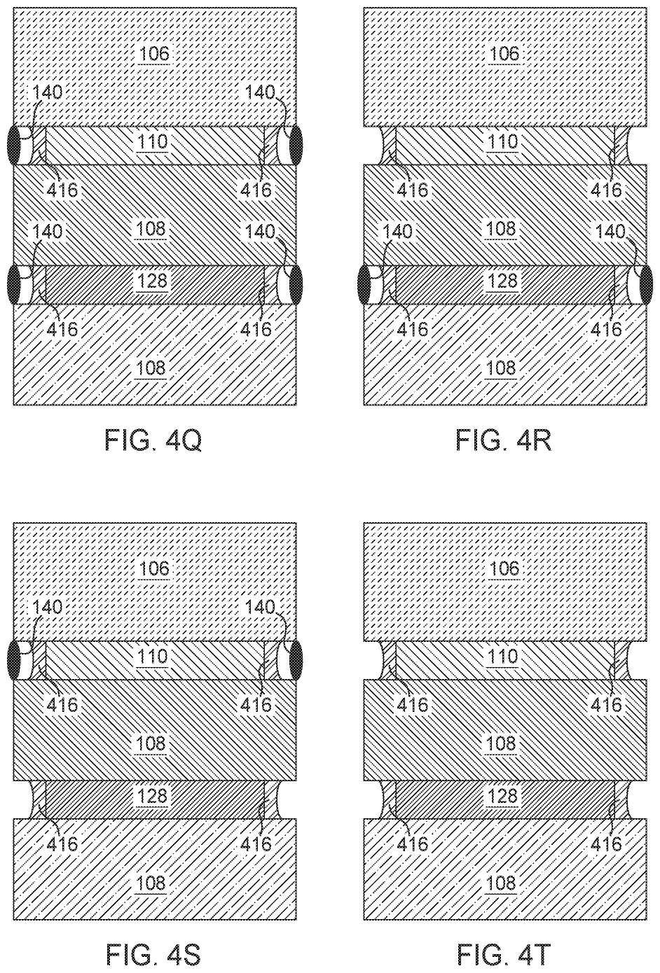

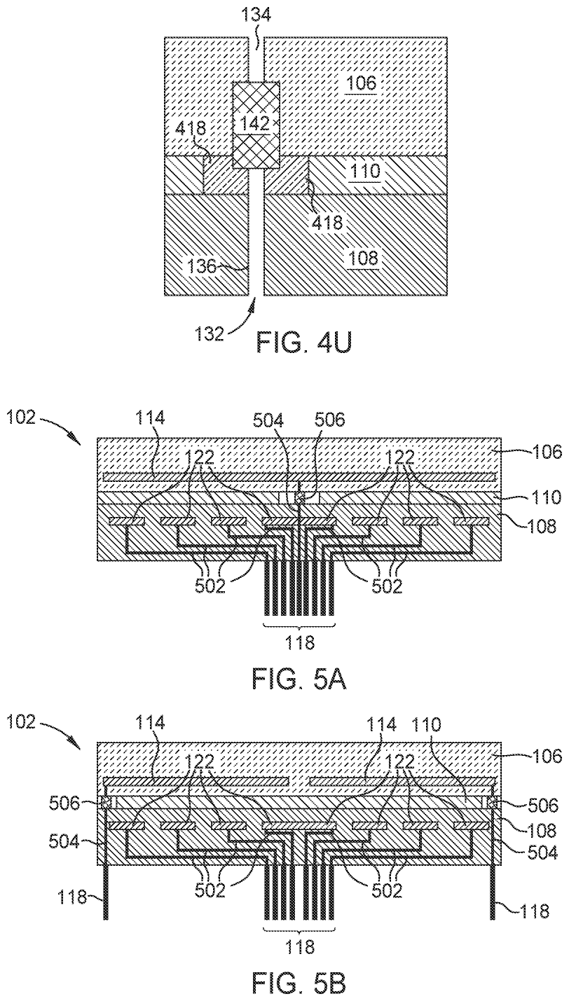

In some embodiments, the bond edge protection features at the periphery of the upper bonding layer 110 are interleaving features, such as steps 402 and protrusions 404, extending from the top ceramic disc 106 through the upper bonding layer 110 and into the bottom ceramic disc 108, as shown in FIGS. 4A, 4B, and 4C. Similar interleaving features are applicable to the bottom ceramic disc 108 and the temperature control base 104 (not shown). The upper surface 104A of the temperature control base 104 may be covered with a thin layer of insulating material. (not shown). These interleaving features on the peripheral edge of the ESC assembly 102 form one or more labyrinths that effectively reduce paths for process gases and process reaction byproducts and substantially prevent those gases and byproducts from reaching the upper bonding layer 110 thus reducing undesirable contamination.

2. Bond Edge Protection with O-Rings or an Encapsulating Layer

In some embodiments, the bond edge protection features at the periphery of the upper bonding layer 110 are seals formed of material resistant to degradation from exposure to the process gases. The seals may also protect the lower bonding layer 128. The seals may be two O-rings 406, each at the periphery of the upper bonding layer 110 and at the periphery of the lower bonding layer 128, as shown in FIG. 4D. The seals may be one O-ring 408 covering both of the periphery of the upper bonding layer 110 and the periphery of the lower bonding layer 128, as shown in FIG. 4E. The seals may be a conformally deposited layer 410 of plasma resistant material, such as Rhodorsil®, PTFE, etc encapsulating the upper bonding layer 110, the bottom ceramic disc 108, and lower bonding layer 128, as shown in FIG. 4F.

3. Bond Edge Protection with Spray Coating

In some embodiments, the bond edge protection features at the periphery of the upper bonding layer 110 are spray coating material 412. The spray coating material 412 may also protect the lower bonding layer 128. Methods of forming such spray coating material 412 at the periphery of the upper bonding layer 110 are described herein.

First, a pocket 414 is formed between the top ceramic disc 106 and the bottom ceramic disc 108, as shown in FIG. 4G. The pocket 414 may have a height between about 0.1 mm and about 20 mm, and a width of between about 0.1 mm and about 10 mm. Subsequently, the pocket 414 is filled with spray coating material 412, as shown in FIG. 4H. Unwanted portion of the spray coating material 412 (e.g., overfill of the spray coating material) is removed by machining, as shown in FIG. 4I. The pocket 414 can be filled with single or multi-layer dielectrics comprising of alumina, rare earth oxides, or a combination of thereof using atomic layer deposition. The unwanted portion of the deposited material 412 may be removed by machining.

4. Bond Edge Protection with a Dissimilar Bond Material

In some embodiments, the bond edge protection features in the first opening 134 (shown in FIG. 1) in the upper bonding layer 110 and/or at the periphery of the upper bonding layer 110 are dissimilar bond material 416 that is different from the upper bonding layer 110. The dissimilar bond material 416 may be disposed adjacent to edges of the upper bonding layer 110 within in the first opening 134 (shown in FIG. 1), as shown in FIG. 4J. The dissimilar bond material 416 may be disposed adjacent to the periphery of the lower bond layer 128 within in the first opening 134, as shown in FIG. 4K. The dissimilar bond material 416 may be disposed adjacent to the periphery of the upper bond layer 110 and to the periphery of the upper bond layer 110 in the first opening 134, with an O-ring 140 in the upper bond layer 110, as shown in FIG. 4L, with O-rings 140 in the upper bond layer 110 and in the lower bond layer 128, as shown in FIG. 4M, with an O-ring 140 in the lower bond layer 128, as shown in FIG. 4N, or without O-rings, as shown in FIG. 4O. The dissimilar bond material 416 may be disposed adjacent to the periphery of the upper bonding layer 110 within the seal, e.g., an O-ring 140, as shown in FIG. 4P. The dissimilar bond material 416 may be disposed adjacent to the periphery of the upper bond layer 110 and the periphery of the lower bond layer 128, with O-rings 140 outside of the upper bond layer 110 and the lower bond layer 128, as shown in FIG. 4Q, with an O-ring 140 outside of the lower bond layer 128, as shown in FIG. 4R, with an O-ring 140 outside of the upper bond layer 110, or without O-rings, as shown in FIG. 4T. The dissimilar bond material 416 may have a convex or concave meniscus and formed of material resistant to halogen plasma corrosion. In some embodiments, plasma resistant polymeric material 418 is disposed adjacent to edges of the upper bonding layer 110, as shown in FIG. 4U, and/or edges of the lower bonding layer 128, without placing an O-ring. The polymeric material 418 may be dissimilar to the upper bonding layer 110 and the lower bonding layer 128.

### Electrical Connection in ESC Assembly

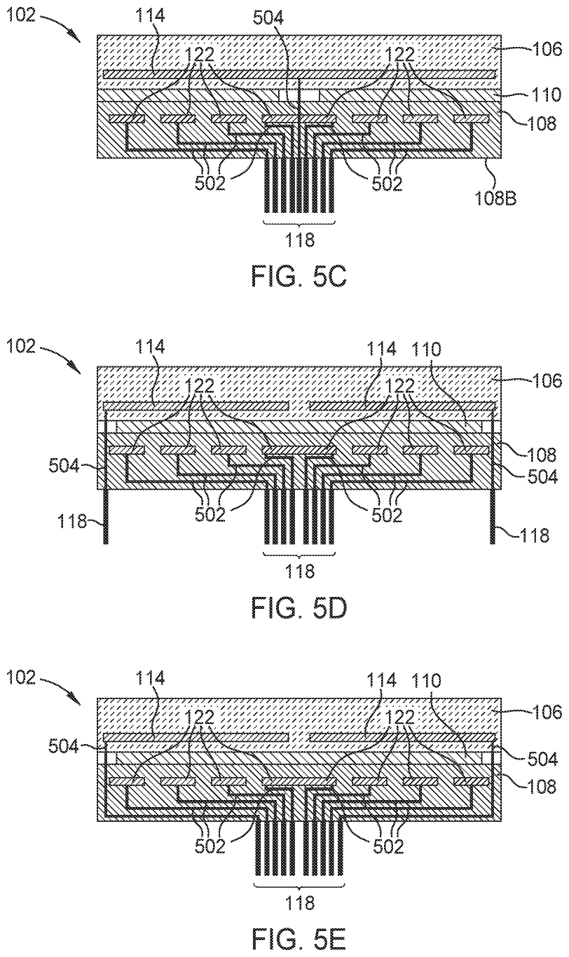

As shown in FIG. 1, the clamp electrodes 114 are embedded within the top ceramic disc 106 and the resistive heaters 122 are embedded within the bottom ceramic disc 108. Referring to FIGS. 5A-5D, the resistive heaters 122 are connected to electric feedthroughs 502 routed through the bottom ceramic disc 108 to the lower surface 108B of the bottom ceramic disc 108, at which the electrical terminals 118 are brazed. The electrical terminals 118 may have different dimensions from one another. The electrical terminals 118 are brazed to a pad (not shown) at the lower surface 108B of the bottom ceramic disc 108, and may each have a featured surface to ensure connections to the pad. The clamp electrodes 114 are connected to electrical feedthroughs 504 that are routed through the ESC assembly 102, including the top ceramic disc 106, the upper bonding layer 110, and the bottom ceramic disc 108, to the lower surface 108B of the bottom ceramic disc 108. Embodiments of such electrical connections for the clamp electrodes 114 within the ESC assembly 102 are described herein.

In some embodiments, an electrical feedthrough 504 connected to a clamp electrode 114 embedded in the top ceramic disc 106 is routed via a metal bump 506 disposed within an opening of the upper bonding layer 110, as shown in FIGS. 5A and 5B. The opening of the upper bonding layer 110 around the metal bump 506 may be filled with dielectric material (e.g., air, epoxy, ceramic or plastic sleeve.) The electrical feedthrough 504 extends from the clamp electrode 114 to the lower surface 108B of the bottom ceramic disc 108 at which the electrical feedthrough 504 contacts an electrical terminal 118, as shown in FIGS. 5A and 5B. The electrical feedthrough 504 may be disposed at the center of the ESC assembly 102 and connected to an electrical terminal 118 at the center of the ESC assembly 102, as shown in FIG. 5A. The electrical feedthroughs 504 may be disposed spaced from the center of the ESC assembly 102 and connected to electrical terminals 118 spaced from the center of the ESC assembly 102 as shown in FIG. 5B.

In some embodiments, an electrical feedthrough 504 connected to a clamp electrode 114 embedded in the top ceramic disc 106 is routed within the top ceramic disc 106 and terminates at a lower surface of the top ceramic disc 106, at which the electrical feedthrough 504 contacts an electrical terminal 118 that extends through an opening of the upper bonding layer 110 and the bottom ceramic disc 108, as shown in FIGS. 5C and 5D. The opening of the upper bonding layer 110 around the electrical terminal 118 may be filled with dielectric material (e.g., air, epoxy, ceramic or plastic sleeve.) The electrical feedthrough 504 may be disposed at the center of the ESC assembly 102 and connected to an electrical terminal 118 at the center of the ESC assembly 102, as shown in FIG. 5C. The electrical feedthroughs 504 may be disposed at the peripheral edge of the ESC assembly 102 and connected to electrical terminals 118 at the peripheral edge of the ESC assembly 102 as shown in FIG. 5D. The electrical feedthrough 504 may be disposed spaced from the center of the ESC assembly 102 and connected to an electrical terminal 118 spaced from the center of the ESC assembly 102, as shown in FIG. 5E.

It should be noted that although one clamp electrode 114 is shown in FIGS. 5A and 5C and two clamp electrodes 114 are shown in FIGS. 5B, 5D, and 5E, there may be more clamp electrodes 114 and corresponding electrical feedthroughs 504 embedded within the ESC assembly 102.

The embodiments described herein provide a substrate support carrier having a top ceramic disc, a bottom ceramic disc, and a bond layer interposed between the top ceramic disc and the bottom ceramic disc. Clamp electrodes are embedded within the top ceramic disc and connected to power sources via electrical feedthroughs routed through the top ceramic disc, the bond layer, and the bottom ceramic disc. Resistive electrodes are embedded within the bottom ceramic disc and connected to power sources via electrical feedthrough routed through the bottom ceramic disc. A porous plug that is a single porous plug or an assembly of multiple porous plugs may be inserted through the top ceramic disc and the bottom ceramic disc. Embodiments of bond edge protection for the bond layer are also described.

While the foregoing is directed to embodiments described herein, other and further embodiments may be devised without departing from the basic scope thereof, and the scope thereof is determined by the claims that follow.

What is claimed is:

1. A substrate support carrier for use in a processing chamber, the substrate support carrier comprising:
an electrostatic chuck (ESC) assembly comprising:
a top ceramic disc having a recess formed from a lower surface of the top ceramic disc;
a bottom ceramic disc having a hole through the bottom ceramic disc;
an upper bonding layer interposed between the lower surface of the top ceramic disc and an upper surface of the bottom ceramic disc; and
a porous plug within at least one of the recess of the top ceramic disc and the hole of the bottom ceramic disc;
a temperature control base; and
a lower bonding layer interposed between a lower surface of the bottom ceramic disc and an upper surface of the temperature control base.

2. The substrate support carrier of claim 1, wherein the porous plug includes an in-situ sleeve at least partially encapsulating the porous plug.

3. The substrate support carrier of claim 1, wherein the porous plug extends within the hole of the bottom ceramic disc and does not extend within the recess of the top ceramic disc.

4. The substrate support carrier of claim 1, wherein the porous plug extends within the recess of the top ceramic disc and does not extend within the hole of the bottom ceramic disc.

5. The substrate support carrier of claim 1, wherein the porous plug comprises a top porous plug extending within the recess of the top ceramic disc and a bottom porous plug extending within the hole of the bottom ceramic disc.

6. The substrate support carrier of claim 5, wherein
the top porous plug is manufactured monolithically as a part of the top ceramic disc, and the bottom porous plug is manufactured monolithically as a part of the bottom ceramic disc.

7. The substrate support carrier of claim 5, wherein the porous plug further comprises a center porous plug between the top porous plug and the bottom porous plug, extending within an opening of the upper bonding layer.

8. A substrate support carrier for use in a processing chamber, the substrate support carrier comprising:
an electrostatic chuck (ESC) assembly comprising:
a top ceramic disc;
a bottom ceramic disc; and
an upper bonding layer interposed between a lower surface of the top ceramic disc and an upper surface of the bottom ceramic disc;
a temperature control base;
a lower bonding layer interposed between a lower surface of the bottom ceramic disc and an upper surface of the temperature control base; and
a bond edge protection feature disposed at edges of at least one of the upper bonding layer and the lower bonding layer.

9. The substrate support carrier of claim 8, wherein the bond edge protection feature comprises one or more protrusions extending from the top ceramic disc through an opening of the upper bonding layer and into the bottom ceramic disc spaced from the center of the substrate support carrier.

10. The substrate support carrier of claim 8, wherein the bond edge protection feature comprises a first O-ring at the periphery of the upper bonding layer and a second O-ring at the periphery of the lower bonding layer.

11. The substrate support carrier of claim 8, wherein the bond edge protection feature comprises an O-ring covering both of the periphery of the upper bonding layer and the periphery of the lower bonding layer.

12. The substrate support carrier of claim 8, wherein the bond edge protection feature comprises a layer of plasma resistant material encapsulating the upper bonding layer, the bottom ceramic disc, and the lower bonding layer.

13. The substrate support carrier of claim 8, wherein the bond edge protection feature comprises spray coating material at the periphery of the upper bonding layer.

14. The substrate support carrier of claim 8, wherein the bond edge protection feature comprises dissimilar bond material disposed at the edges of the at least one of the upper bonding layer and the lower bonding layer.

15. The substrate support carrier of claim 8, wherein the bond edge protection feature comprises plasma resistant polymeric material disposed at the edges of the upper bonding layer.

16. An electrostatic chuck (ESC) assembly comprising:
a top ceramic disc having a clamp electrode embedded therein;
a bottom ceramic disc having a plurality of resistive heaters embedded therein;
a bonding layer interposed between a lower surface of the top ceramic disc and an upper surface of the bottom ceramic disc;
a first electrical feedthrough connected to the clamp electrode;
a plurality of second electrical feedthroughs each connected to one of the plurality of resistive heaters and routed within the bottom ceramic disc to the lower surface of the bottom ceramic disc; and
a plurality of electrical terminals brazed at the lower surface of the lower surface of the bottom ceramic disc.

17. The ESC assembly of claim 16, further comprising:
a metal bump within an opening of the bonding layer at the center of the ESC assembly, wherein
the first electrical feedthrough is routed via the metal bump and connected to one of the plurality of electrical terminals at the lower surface of the bottom ceramic disc at the center of the ESC assembly.

18. The ESC assembly of claim 16, further comprising:
a metal bump within an opening of the bonding layer spaced from the center of the ESC assembly, wherein
the first electrical feedthrough is routed via the metal bump to the lower surface of the bottom ceramic disc spaced from the center of the ESC assembly.

19. The ESC assembly of claim 16, wherein
the first electrical feedthrough is routed within the top ceramic disc and connected to one of the plurality of electrical terminals that extends through an opening of the bonding layer and through the bottom ceramic disc at the center of the ESC assembly.

20. The ESC assembly of claim 16, wherein
the first electrical feedthrough is routed within the top ceramic disc and connected to one of the plurality of electrical terminals that extends through an opening of the bonding layer and through the bottom ceramic disc spaced from the center of the ESC assembly.
